(19) United States
(12) Patent Application Publication
(10) Pub. No.: US 2024/0195417 A1
(43) Pub. Date: Jun. 13, 2024

(54) INPUT STAGES FOR OPTO-EMULATORS

(71) Applicant: Texas Instruments Incorporated, Dallas, TX (US)

(72) Inventors: Avinash Shah, Jharsuguda (IN); Kashyap Barot, Bangalore (IN); Sreeram Nasum S, Bangalore (IN); Kumar Anurag Shrivastava, Bangalore (IN); Suvadip Banerjee, Bangalore (IN)

(21) Appl. No.: 18/525,464

(22) Filed: Nov. 30, 2023

(30) Foreign Application Priority Data
Dec. 13, 2022 (IN) 202241071889

(51) Int. Cl. H03K 19/017; G05B 19/05; H03K 19/003; H03K 19/0185

(52) U.S. Cl. CPC H03K 19/01728; G05B 19/054; H03K 19/00361; H03K 19/00384; H03K 19/018557; H03K 19/017572

(57) ABSTRACT

An example apparatus includes: a current mirror having first and second outputs; oscillator circuitry including: a first transistor having a first terminal coupled to the first output of the current mirror, having a second terminal, and having a control terminal; and a second transistor having a first terminal coupled to the first output of the current mirror, having a second terminal coupled to the control terminal and the second terminal of the first transistor, and having a control terminal coupled to the second terminals of the first and second transistors; and current shunt circuitry having a terminal coupled to the second output of the current mirror.

### CROSS-REFERENCE TO RELATED APPLICATION

This patent application claims the benefit of and priority to India Provisional Patent Application Serial No. 202241071889, entitled ARCHITECTURE FOR INPUT STAGE OF HIGH SPEED, HIGH CMTI OPTO-EMULATOR, which was filed on Dec. 13, 2022, which Application is hereby incorporated herein by reference in its entirety.

### TECHNICAL FIELD

This description relates generally to electronic circuits and, more particularly, to input stages for opto-emulators.

### BACKGROUND

Opto-couplers include a light source, e.g., a light emitting diode, on a transmitter side and a photodetector, e.g., a photo-transistor, on a receiver side, which are separated from each other by an isolation barrier. Some opto-couplers include two input connections (e.g., an anode and a cathode), a ground connection, a supply connection, and an output connection. When a signal at the input connection (e.g., an input current) is high, the output is at a first logic level, and when the signal at the input connection is low (e.g., zero), the output is at a second logic level. An opto-emulator emulates the operation of an opto-coupler but without the light source and the photodetector, and can be operated at higher speeds than some opto-couplers.

### SUMMARY

In one example, a circuit includes a current mirror having first and second outputs; oscillator circuitry including: a first transistor having a first terminal coupled to the first output of the current mirror, having a second terminal, and having a control terminal; and a second transistor having a first terminal coupled to the first output of the current mirror, having a second terminal coupled to the control terminal and the second terminal of the first transistor, and having a control terminal coupled to the second terminals of the first and second transistors; and current shunt circuitry having a terminal coupled to the second output of the current mirror.

In another example, a circuit includes a current mirror having first and second outputs; oscillator circuitry including: a first transistor having a first terminal coupled to the first output of the current mirror, having a second terminal, and having a control terminal; and a second transistor having a first terminal coupled to the first output of the current mirror, having a second terminal coupled to the control terminal and the second terminal of the first transistor, and having a control terminal coupled to the second terminals of the first and second transistors; and oscillator disable circuitry having a first terminal coupled to the second terminal of the current mirror.

In another example, a circuit includes a transmitter circuit having: a current mirror circuit including a first output, a second output, and a third output; an oscillator circuit having an input coupled to the first output of the current mirror circuit, a first output, and a second output; and current shunt circuitry having a terminal coupled to the second output of the current mirror circuit; and oscillator disable circuitry having a first terminal coupled to the third output of the current mirror circuit; a receiver circuit having first and second inputs; and an isolation circuit having first and second terminals coupled to the first and second outputs of the oscillator circuit and third and fourth terminals coupled to the first and second inputs of the receiver circuit.

### BRIEF DESCRIPTION OF THE DRAWINGS

FIG. 1 is a block diagram of a system including a sensor, an example opto-emulator, and a processor.

FIG. 2 is a block diagram of an example of a transmitter die of FIG. 1.

FIG. 3 is a block diagram of an example of a receiver die of FIG. 1.

FIG. 4 is an example circuit diagram of the transmitter die of FIG. 1 and FIG. 2.

FIG. 5 is a circuit diagram of an example oscillator of the transmitter die of FIG. 1 and FIG. 2 coupled to an example winding of a transformer of the isolation die of FIG. 1.

FIG. 6 is a circuit diagram of an example discharge circuit of the transmitter die of FIG. 2.

FIG. 7 is a graph of voltage-current (V-I) characteristics of a circuit without oscillator disable circuitry of the transmitter die of FIG. 1 and FIG. 2 and a graph of the V-I characteristics of the circuit with the oscillator disable circuitry.

FIG. 8 is a graph of bias current to input current of example current shunt circuitry of the transmitter die of FIG. 1 and FIG. 2.

FIG. 9 includes graphs illustrating improvements provided by example discharge circuitry and example clamp circuitry of the transmitter die of FIG. 2.

The same reference numbers or other reference designators are used in the drawings to designate the same or similar (functionally and/or structurally) features.

### DETAILED DESCRIPTION

Opto-couplers that include light emitting diodes rely on light switching times when signaling, e.g., the time required to turn the light emitting diodes on and off. Such light switching times impede the data rate that may be utilized with opto-couplers. Furthermore, if common mode noise is coupled across the isolation barrier of the opto-coupler, an output signal of the opto-coupler can change its polarity during such transient noise events. The resilience of a circuit to such noise is known as Common Mode Transient Immunity (CMTI).

The example apparatus described herein, and referred to as opto-emulators or portions thereof, may provide improved switching times and/or CMTI by emulating the isolation characteristics of an opto-coupler without the use of a light emitting diode. Some input stages of opto-emulators described herein include a center-tapped transformer and/or a cross coupled oscillator to improve CMTI performance. In an example, CMTI is increased from 25 kilovolts per microsecond (kV/μs) for an opto-coupler to 100 kV/μs for an opto-emulator. Some input stages for opto-emulators described herein include current shunt circuitry and/or oscillator disable circuitry to emulate diode VI characteristics for a wide input current range, for instance between 2 mA and 20 mA. Some input stages for opto-emulators described herein include discharge circuitry and/or clamp circuitry to reduce overshoot and provide circuit control to increase bandwidth capabilities. In an example, bandwidth is increased from 15 Mbps for an opto-coupler to 25 Mbps for an opto-emulator.

While various circuitry components and improvements are described, any combination of such circuitry components may be utilized. For example, an opto-emulator may include any one or more of the center-tapped transformer, the cross coupled oscillator, the current shunt circuitry, the oscillator disable circuitry, the discharge circuitry, and/or the clamp circuitry.

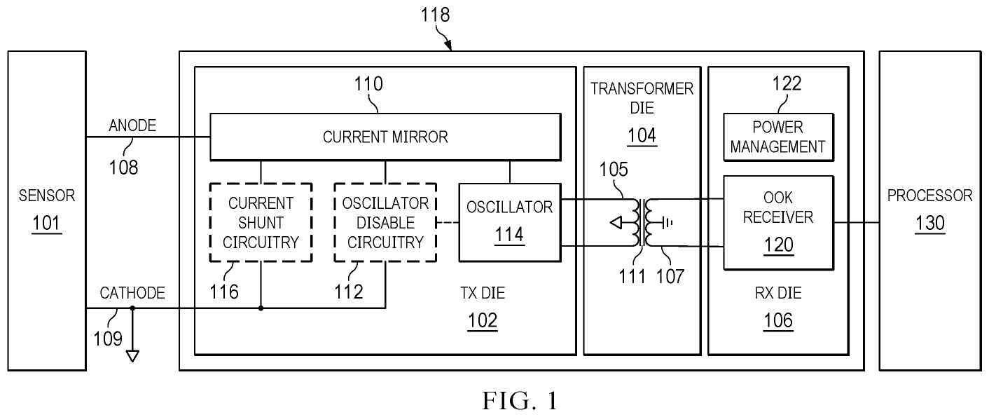

FIG. 1 is a diagram of an example system 100 including a sensor 102, an opto-emulator 118, and a processor 130. In some examples, the system 100 is a programmable logic controller (PLC) system or a servo drive system. In some examples, the sensor 102 may be a pulse encoder. For example, the sensor 101 is part of a controller that provides a communication signal that is to be transmitted to a processor 130 of a transceiver connected to an output of the receiver die 106, for example as part of an automotive controller area network (CAN) system. In some examples, the system 100 may include multiple sensors and multiple opto-emulators. In such examples, each sensor may have its own opto-emulator to transfer sensor data to the processor 130. As another option, multiple sensors may share an opto-emulator. As another option, the system 100 may include multiple processors.

The opto-emulator 118 includes a transmitter die 102, an isolation die 104, and a receiver die 106. The sensor 101 is coupled to and signals the transmitter die 102, which signals the receiver die 106 via the isolation die 104. The receiver die 106 signals the processor 130. In the illustrated example, the isolation die 104 includes a transformer having a first winding 105 separated from a second winding 107 by an isolation barrier 111. Both the first and second windings have a third terminal coupled to the ground terminal, e.g., center tapped to the ground terminal or to ground. As such, the isolation die 104 is also referred to as a transformer die 104, and the transformer die is referred to as being center tapped to a ground terminal or to ground.

The transformer die 104 isolates the transmitter die 102 and the sensor 101 from the receiver die 106 and the processor 130. In this example, there is no direct current (DC) path between the winding 105 of the transformer die 104 that is coupled to the transmitter die 102 and the winding 107 of the transformer die 104 that is coupled to the receiver die 106. Such isolation may be important when working with sensitive equipment, working with environments that include significant noise, such as automotive implementations, motor drive systems, factory systems, etc., working with environments that have significant voltage differences, such as high voltage systems connected to low voltage control systems, etc.

In an example, the sensor 101, the opto-emulator 118, and the processor 130 are included in a same integrated circuit (IC) or die package or on a same printed circuit board. In other examples, the sensor 101, the opto-emulator 118, and the processor 130 are included in multiple IC packages. For example, the sensor 101 and the processor 130 are included in first and second IC packages, and the opto-emulator 118 is included in a third IC package.

As shown, the sensor 101 has first and second terminals. The transmitter die 102 has first and second terminals, labeled as an anode 108 and a cathode 109. The anode 108 is coupled to the first output of the sensor 102, and the cathode 109 is coupled to the second output of the sensor 101. The cathode 109 is also coupled to a voltage terminal, for instance a ground terminal that receives a ground or common voltage.

The transmitter die 102 includes a current mirror 110 and an oscillator 114, and may further include oscillator disable circuitry 112, or current shunt circuitry 116, or both oscillator disable circuitry 112 and current shunt circuitry 116. The current mirror 110 has an input coupled to the anode 108 and has first, second, and third outputs. The input of the current mirror 110 is shown as being directly connected to the anode 108. However, in other examples, the input of the current mirror 110 is coupled to the anode 108 via other circuitry.

The current shunt circuitry 116 has a first terminal coupled to the first output of the current mirror 110 and a second terminal coupled to the cathode 109. The oscillator disable circuitry 112 has a first terminal coupled to the second output of the current mirror 110. The oscillator disable circuitry 112 also has a second terminal coupled to the oscillator 114 and a third terminal coupled to the cathode 109 to disable the oscillator 114 by selectively shunting the input of the oscillator 114 to the cathode 109. The oscillator 114 has an input coupled to the third output of the current mirror 110, a first output coupled to a first end or terminal of the winding 105 of the transformer die 104, and a second output coupled to a second end or terminal of the winding 105 of the transformer die 104.

The receiver die 106 includes an on-off keying (OOK) receiver 120 and power management circuitry 122. The OOK receiver 120 includes a first input coupled to a first end or terminal of the winding 107 of the transformer die 104, a second input coupled to a second end or terminal of the winding 107 of the transformer die 104, and an output. The output of the OOK receiver 120 is coupled to an input of the processor 130.

In some examples, the sensor 101 operates to generate or modulate a current responsive to an ambient parameter sensed by the sensor 101. The sensor 101 may be any type of sensor to collect data and transmit the data to the processor 130 via the transmitter die 102, the transformer die 104, and the receiver die 106. Alternatively, any other type of input to the transmitter die 102 may be utilized. For example, the input to the transmitter die 102 is a user input device, a communication device, a controller, a processor, etc.

The transmitter die 102 implements an input stage of an the opto-emulator 118. The transmitter die 102 receives a current generated or modulated by the sensor 101 and generates a transmit signal at the terminals of the oscillator 114. In an example, the current mirror 110 provides bias currents to the oscillator 104 and other circuitry of the transmitter die 102, for example the oscillator disable circuitry 112 and the current shunt circuitry 116. In an example, the oscillator 114 (when enabled or turned on) energizes the transmitter side of the transformer die 104 to transfer a signal to the receiver side of the transformer die 104 and, thereby, to the receiver die 106. In an example, the current shunt circuitry 116 limits current to the oscillator 114 above a threshold current. This aids in reducing emissions and improving reliability of the oscillator 114.

In an example, the oscillator disable circuitry 112 (also referred to as power-on-reset (POR) circuitry 112) selectively couples the input of the oscillator 114 to the ground terminal to pull the input to ground when the POR circuitry 112 senses an insufficient input voltage (e.g., less than 0.8 V). For example, the POR circuitry 112 may keep the oscillator 114 turned off or disabled until a current source reaches a desired current. In an example while disabled, the oscillator 114 does not provide a transmit signal at its terminals. Thus, the POR circuitry 112 facilitates glitch-free or reduced glitch oscillator operation by keeping the oscillator turned off until voltage and/or current levels are sufficient. As used herein, a glitch is an unwanted spike, valley, perturbation, discontinuity, etc. in an input or output signal of a device.

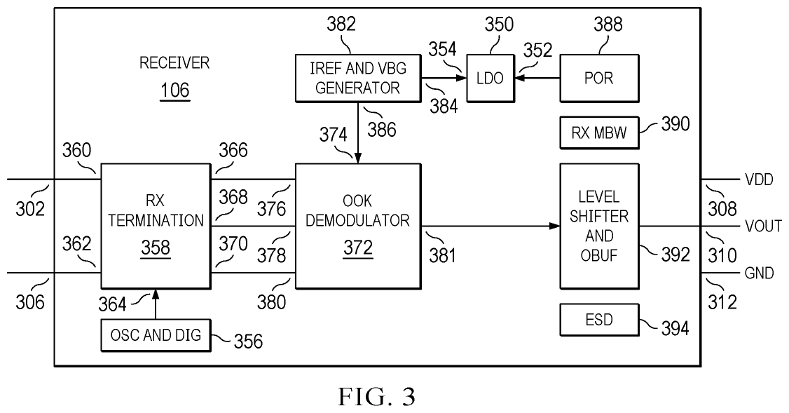

As described in further detail in conjunction with FIG. 3, an example of the oscillator circuitry 114 is a cross coupled oscillator including a first p-channel metal-oxide semiconductor (PMOS) transistor and a second PMOS transistor. The PMOS cross coupled oscillator circuitry improves the CMTI of the transmission die 102. An example center tapped transformer of the transformer die 104 may further improve the CMTI of the transmission die 102. When common mode noise is present between the grounds of the transformer die 104 coupled to the oscillator 114, there may exist a common mode current due to parasitic capacitance between the two grounds of the transformer die 104. The center tapped transformer die 104 with ground as the center tap connection allows common mode currents to directly flow from one end of the center-tap to the other end of center tap without any interference to transmitter die 102 or receiver die 106. Although the PMOS cross coupled oscillator provides CMTI advantages, a transmitter die 102 may be implemented with any other type of oscillator, for example if the CMTI advantages are not desired for a particular implementation.

The transformer die 104 operates to: receive the transmit signal from the transmitter die 102; and provide a modified transmit signal to the receiver die 106. Relative to the transmit signal provided by the transmitter die 102, the modified transmit signal received by the receiver die 106 may vary with regard to voltage level, current level, and/or polarity.

The receiver die 106 includes the on-off keying (OOK) receiver circuitry 120 to demodulate the received signal. The receiver die 106 also includes the power management circuitry 122 to manage power utilization (e.g., waking, sleeping, etc.) of the receiver die 106. The receiver die 106, provides an output signal to the processor 130.

FIG. 1 includes an example receiver die 106 with the OOK receiver circuitry 120 and the power management circuitry 122. However, any other type of receiver may be coupled to the transformer die 104. For example, the receiver die 106 may be coupled to an automotive system, to a motor controller, to a motor, to a central controller, to a network interface, etc. The components of a particular implementation of the receiver die 106 may be selected based on the particular application/implementation of the system.

The processor 130 may operate to: store, analyze, and/or modify the output signal provided by the receiver die 106. The processor 130 may be any type of processor to process data from the sensor 101 that is received at the processor 130 from the receiver die 106. Alternatively, any other type of device may be coupled to the output of the receiver die 106 such as, for example, a controller, a re-transmitter, a communication device, etc.

In operation, an input signal from the sensor 101 is provided across the anode 108 and the cathode 109. For example, the input signal may be a communication signal from a controller that is to be transmitted to a transceiver connected to an output of the receiver die 106 (e.g., an automotive controller area network (CAN) system). The current mirror 110 converts the input signal into a bias current to power the oscillator 114 when the oscillator 114 is not disabled by the oscillator disable circuitry 112. The oscillator 114 energizes the transmitter side of the transformer die 104 to transfer the signal to the receiver side of the transformer die 104 and, thereby, to the receiver die 106, which outputs the signal to the processor 130.

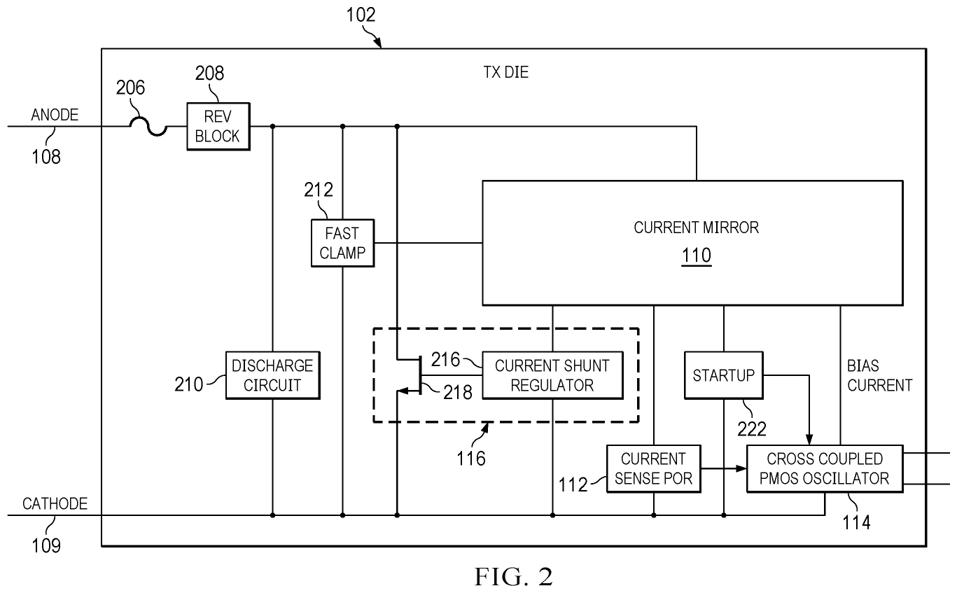

FIG. 2 is a block diagram of an example implementation of the transmitter die 102 of FIG. 1. The transmitter die 102 of FIG. 2 has the anode 108 and the cathode 109, and includes the current mirror 110, the oscillator disable circuitry (or current sense POR) 112, the oscillator 114, and the current shunt circuitry 116. The example transmitter die 102 further includes a fuse 206, a reverse blocking switch circuitry 208, a discharge circuit 210, a fast clamp circuitry 212, and a startup circuitry 222.

The reverse blocking switch circuitry 208 includes an input and an output. The reverse blocking switch circuitry 208 provides reverse current protection. For example, the reverse blocking switch circuitry 208 may be implemented by a transistor load switch that provides reverse current protection so that current does not flow towards the anode 108. Alternatively, any other circuitry to prevent reverse current flow towards to the anode 108 may be utilized.

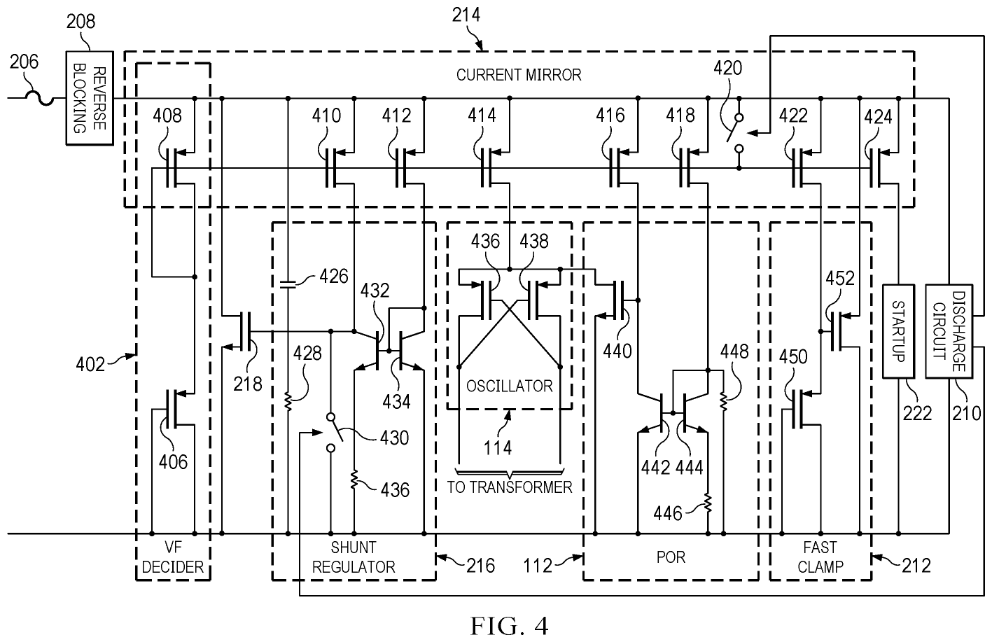

The current mirror 214 includes an input, a first output, a second output, a third output, a fourth output, and a fifth output. In an example, the current mirror 214 provides oscillator-scaled bias currents to the current shunt regulator 216, the current sense POR 112, the startup circuitry 222, the oscillator circuitry 114, and the clamp circuitry 212. Example circuitry to implement the current mirror 214 is described in conjunction with FIG. 4 and FIG. 5. Alternatively, any other circuitry and/or circuit configuration to produce a copy of the current at an input terminal by replicating the current in an output terminal may be utilized.

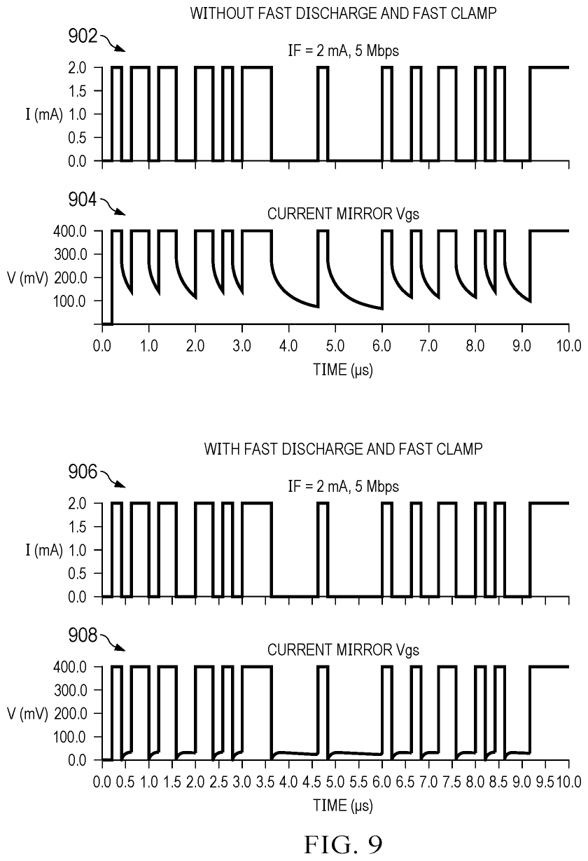

The discharge circuit 210 includes an input and an output. The discharge circuit 210 detects a termination/cessation of the input current and quickly discharges all internal nodes to reduce inter-symbol interference (ISI). The discharge circuit 210 may be implemented by a transistor in which the gate may be biased to short the anode 108 to the cathode 109 (e.g., to ground). Shorting the anode 108 to the cathode 109 discharges any stored energy within the circuit to drive the output signal low quickly, rather than an output that slowly ramps to a low value. Signal improvements provided by the discharge circuit 210 are discussed in conjunction with FIG. 9.

The fast clamp circuitry 212, also referred to simply as clamp circuitry 212, includes a first input, a second input, and an output. The fast clamp circuitry 212 reduces overshoot for fast input current transients and prevents false trigger of the discharge circuit 210 during fast input current transients. The fast clamp circuitry 212 is off in the DC condition and does not interfere with operation of other circuitry. However, responsive to input current that is very high in the transient condition, the fast clamp is enabled and limits the overshoot.

As shown, the current shunt circuitry 116 includes a current shunt regulator 216 coupled to a current shunt transistor 218. The current shunt transistor 218 is implemented as an n-channel metal-oxide semiconductor (NMOS) transistor. In other examples, the current shunt transistor 218 is implemented as a different type of field-effect transistor (FET) or a different type of transistor. Such an implementation may depend, at least in part, on the circuit arrangement of the current shunt regulator 216. As used herein, transistors include first and second terminals (e.g., a source and a drain in a FET) and a control terminal (e.g., a gate in a FET). The current shunt regulator 216 includes an input, a first output, and a second output. The current shunt regulator 216 drives the shunt transistor 218 to limit the oscillator current after getting sufficient current into the oscillator 114. Such limiting reduces emissions and improves reliability to improve the input current range. High bandwidth and phase margin avoids overshoot and undershoot during fast transient conditions.

The current sense POR 112 includes an input, a first output, and a second output. The current sense POR 112 turns off the oscillator 114 below a threshold voltage (e.g., 0.8V input voltage) and facilitates glitch free or reduced glitch oscillator current for different input ramp conditions.

The startup circuitry 222 includes an input, a first output, and a second output. The startup circuitry 222 provides a pulse trigger to the oscillator 114 for fast, reliable oscillator start for higher bandwidth. Any suitable circuitry, for example, including one or more transistors operatively coupled together, can be used to implement the startup circuitry 222.

The oscillator 114 includes a first input, a second input, a third input, a first output, and a second output. The oscillator 114 operates as the transmitter core to provide improved CMTI. The example oscillator circuitry is a PMOS cross coupled oscillator. As shown in FIG. 5, when the PMOS cross coupled oscillator 114 is connected to a grounded center tap from the transformer (e.g., transformer 104), CMTI current flows directly from the center-tap without affecting the internal Vdd of the oscillator.

In the transmitter die 102, the anode 108 is coupled to an input of the fuse 206. An output of the fuse 206 is coupled to the input of the reverse blocking switch circuitry 208. The output of the reverse blocking switch circuitry 208 is coupled to the input of the current mirror 214. The output of the reverse blocking switch circuitry 208 is coupled to a first input terminal of the discharge circuit 210. The output of the reverse blocking switch circuitry 208 is coupled to the first input of the fast clamp circuitry 212. The output of the reverse blocking switch circuitry 208 is coupled to the drain of the shunt transistor 218.

In the transmitter die 102, the first output of the current mirror 214 is coupled to the input of the current shunt regulator 216. The second output of the current mirror 214 is coupled to the input of the current sense POR 112. the third output of the current mirror 214 is coupled to the input of the startup circuitry 222. The fourth output of the current mirror 214 is coupled to the input of the oscillator 114. The fifth output of the current mirror 214 is coupled to the second input of the clamp circuitry 212. In the transmitter die 102, the first output of the current shunt regulator 216 is coupled to the gate of the shunt transistor 218. In the transmitter die 102, the cathode 109 is coupled to the output of the discharge circuit 210, the output of the fast clamp 212, the output the current shunt regulator 216, the output of the current sense POR 112, and the output of the startup 222. In the transmitter die 102, the second input of the oscillator 114 is coupled to the output of the startup 222 and the third input of the oscillator 114 is coupled to the output of the current sense POR 112. Also, the first output of the oscillator 114 is coupled to a first end or terminal of the winding 105, and the second output of the oscillator 114 is coupled to a second end or terminal of the winding 105.

Example circuitry that may implement components of the transmitter die 102, the transformer 104, and the receiver die 106 are described in U.S. patent application Ser. No. 18/194,267, filed Mar. 31, 2023, and India Patent Application Serial No. 202241071844, filed Dec. 13, 2022, both of which are hereby incorporated by reference herein.

FIG. 2 illustrates a particular combination of components. However, other combinations and sub-combinations of the components may be selected for a particular implementation or application. For example, when concerned with the DC performance and slow ramp performance emulating a diode, an input stage may include the current shunt regulator 216, the current sense POR 112, the current mirror 214, and the reverse blocking switch 208. When concerned with fast transient performance as compared with an LED-based opto-coupler, an input stage may include the discharge circuitry 210 and the fast clamp circuitry 212. When concerned with improving CMTI performance as compared with an LED-based opto-coupler, an input stage may include the PMOS cross coupled oscillator 114 and a center tapped isolating transformer 104.

FIG. 3 is a block diagram of an example of the receiver die 106 in FIG. 1. The receiver 106 has a first terminal 302 that is an input, a second terminal 306 is an input, a fourth terminal 308 to provide an operating voltage (VDD), a fifth terminal 310 that is an output, and a sixth terminal 310 coupled to ground. The input 302 is coupled to a first end or terminal of the winding 107, and the input 306 is coupled to a second terminal or end of the winding 107.

As shown, the receiver 106 includes a low dropout regulator (LDO) 350, oscillator and digital circuitry 356, a receiver (RX) termination circuit 358, an on-off keying (OOK) demodulator 372, a reference current (IREF) and bandgap voltage reference (VBG) generator 382, a power-on reset (POR) circuit 388, an RX missing bondwire (MBW) circuit 390, a level shifter and output buffer (OBUF) circuit 392, and an ESD circuit 394.

The LDO 350 has a first terminal 352 and a second terminal 354. The oscillator and digital circuitry 356 has an output. The RX termination circuit 358 has a first terminal 360, a second terminal 362, a third terminal 364, a fourth terminal 366, a fifth terminal 368, and a sixth terminal 370. The OOK demodulator has a first terminal 374, a second terminal 376, a third terminal 378, a fourth terminal 380, and a fifth terminal 381. The IREF and VBG generator 382 has a first terminal 384 and a second terminal 386. The POR circuit 388 has an output. The level shifter and OBUF circuit 392 has an input and an output. The ESD circuit 394 provides ESD protection for the receiver 106. The RX MBW circuit 390 operates to detect faulty or missing bondwires. For example, such bondwires may be used to couple the transformer 104 to the first terminal 302 of the receiver 106 and/or to couple the transformer 104 to the third terminal 306 of the receiver 106.

In the example of FIG. 3, first terminal 352 of the LDO 350 is coupled to the output of the POR circuit 388. The second terminal 354 of the LDO 350 is coupled to the first terminal 384 of the IREF and VBG generator 382. The first terminal 360 of the RX termination circuit 358 is coupled to the first terminal 302 of the receiver 106. The second terminal 362 of the RX termination circuit 358 is coupled to the third terminal 306 of the receiver 106. The third terminal 364 of the RX termination circuit 358 is coupled to the output of the oscillator and digital circuitry 356. The fourth terminal 366 of the RX termination circuit 358 is coupled to the second terminal 376 of the OOK demodulator 372. The fifth terminal 368 of the RX termination circuit 358 is coupled to the third terminal 378 of the OOK demodulator 372. The sixth terminal 370 of the RX termination circuit 358 is coupled to the fourth terminal 380 of the OOK demodulator 372. The first terminal 374 of the OOK demodulator 372 is coupled to the second terminal 386 of the IREF and VBG generator 382. The fifth terminal 381 of the OOK demodulator 372 is coupled to the input of the level shifter and OBUF circuit 392. The output of the level shifter and OBUF circuit 392 is coupled to the fifth terminal 310 of the receiver 106.

In some examples, the LDO 350, the POR circuit 388, the RX MBW circuit 390, and the ESD circuit 394 are part of a first voltage domain (e.g., a 5V domain) of the receiver 106. The oscillator and digital circuitry 356, the RX termination circuit 358, the OOK demodulator 372, and the IREF and VBG generator 382 are part of a second voltage domain (e.g., a 1.8V domain) of the receiver 106. Also, the level shifter and OBUF circuit 392 is part of a third voltage domain (e.g., a 6.8V domain) of the receiver 106.

In some examples, the receiver 106 includes various power management circuits such as the POR circuit 388, the IREF and VBG generator 382, and the LDO 350. The receiver 106 may operate based on a voltage supply provided by the LDO 350 to detect the OOK carrier transmitted by the transmitter 102 as either logic 0 or logic 1. The output signal of the OOK demodulator 372 may be in the LDO supply domain. The level shifter and OBUF circuit 392 is used to convert the output signal of the OOK demodulator from LDO voltage supply domain to a VDD supply domain signal. The OBUF operation of the level shifter and OBUF circuit 392 is used to send the output signal to a larger load.

In some examples, the receiver 106 operates to: receive the modified transmit signal; perform mixing operations on the modified transmit signal based on signals provided by the oscillator and digital circuitry 356; use the OOK demodulator 372 to perform OOK demodulation on the mixed signals responsive to IREF and/or VBG from the IREF and VBG generator 382; use the level shifter and OBUF circuit 392 to level shift and buffer the demodulated signals generated by the OOK demodulator 372, resulting in VOUT at the output of the level shifter and OBUF circuit 392; and provide VOUT at the fifth terminal 170 of the receiver 106. During receiver operations, VDD is used to power the signal output by the level shifter and OBUF circuit 392. As needed, the ESD circuit 394 provides ESD protection.

FIG. 4 is an example circuit diagram of the transmitter die 102 of FIG. 1 and FIG. 2. The transmitter die circuitry 102 of FIG. 4 includes the fuse 206, the reverse blocking switch 208, forward voltage (VF) circuitry 402, the current mirror 214, the current shunt regulator 216, the shunt transistor 218, the oscillator 114, the POR circuitry 112, the startup 222, and the discharge circuit 210.

The VF circuitry 402 and the current mirror 214 share a first transistor 408. The VF circuitry 402 includes a second transistor 406. The current mirror circuitry 214 additionally includes a third transistor 410, a fourth transistor 412, a fifth transistor 414, a sixth transistor 416, a seventh transistor 418, a first switch 420, an eighth transistor 422, and a ninth transistor 424. The current shunt regulator 216 includes a first capacitor 426, a second switch 430, a tenth transistor 432, an eleventh transistor 434, a first resistor 428, and a second resistor 435. The oscillator 114 includes a twelfth transistor 436 and a thirteenth transistor 438. The POR circuitry 112 includes a fourteenth transistor 440, a fifteenth transistor 442, a sixteenth transistor 444, a third resistor 446, and a fourth resistor 448. The fast clamp circuitry 212 includes a seventeenth transistor 450 and an eighteenth transistor 452. The switches 420 and 430 may be implemented as one or more transistors, such as one or more FETs.

An input terminal of the fuse 206 is coupled to the anode 108. An input terminal of the reverse blocking switch 208 is coupled to an output terminal of the fuse 206. An output terminal of the reverse blocking switch 208 is coupled to source terminals of the first transistor 408, the third transistor 410, the fourth transistor 412, the fifth transistor 414, the sixth transistor 416, the seventh transistor 418, the eighth transistor 422, and the ninth transistor 424; a drain terminal of the shunt transistor 218, a first terminal of the first capacitor 426, a first terminal of the switch 420, a source of the eighteenth transistor 452, and an input terminal of the discharge circuitry 210.

A gate of the first transistor 408 is coupled to the drain of the first transistor 408, a source of the second transistor 406, a second terminal of the first switch 420, and to the gates of the third transistor 410, the fourth transistor 412, the fifth transistor 414, the sixth transistor 416, the seventh transistor 418, the eight transistor 422, and the ninth transistor 424. A gate and a drain of the second transistor 406 are coupled to the cathode 109.

A second terminal of the capacitor 426 is coupled to a gate of the shunt transistor 218, a first terminal of the first resistor 428, a drain of the third transistor 410, a first terminal of the second switch 430, and a collector of the tenth transistor 432. A second terminal of the first resistor 428 is coupled to the cathode 109.

A second terminal of the second switch 430 is coupled to the cathode 109. A control terminal of the second switch 430 is coupled to the discharge circuit 210 to allow the discharge circuit 210 to close the second switch 430 to pull the signal input from anode 108 to be pulled to the cathode 109 (e.g., to ground).

A gate of the tenth transistor 432 is coupled to a drain of the fourth transistor 412, a collector of the eleventh transistor 434, and a gate of the eleventh transistor 434. An emitter of the tenth transistor 432 is coupled to a first terminal of the second resistor 435. A second terminal of the second resistor 435 is coupled to the cathode 109. An emitter of the eleventh transistor 434 is coupled to the cathode 109.

Source terminals of the twelfth transistor 436 and the thirteenth transistor 438 are coupled to a drain terminal of the fifth transistor 414. A gate terminal of the twelfth transistor 436 is coupled to a drain of the thirteenth transistor 438, which is coupled to the transformer 104. A gate terminal of the thirteenth transistor 438 is coupled to a drain of the twelfth transistor 436, which is coupled to the transformer 104. An example illustrating connection of the oscillator 114 to the transformer 104 is described in conjunction with FIG. 5.

A drain of the fourteenth transistor 440 is coupled to the drain of the fifth transistor 414. A gate of the fourteenth transistor 440 is coupled to a drain of the sixth transistor 416 and a collector of the fifteenth transistor 442. A gate of the fifteenth transistor 442 is coupled to a drain of the seventh transistor 418, a collector of the sixteenth transistor 444, a gate of the sixteenth transistor 444, and a first terminal of the fourth resistor 448. An emitter of the fifteenth transistor 442 is coupled to the cathode 109. An emitter of the sixteenth transistor 444 is coupled to a first terminal of the third resistor 446. A second terminal of the third resistor 446 is coupled to the anode cathode. A second terminal of the fourth resistor 448 is coupled to the cathode 109.

A gate of the of the seventeenth transistor 450 is coupled to the cathode 109. A source of the seventeenth transistor 450 is coupled to a drain of the eight transistor 422 and a gate of the eighteenth transistor 452. A drain of the seventeenth transistor 450 is coupled to the cathode 109. A drain of the eighteenth transistor 452 is coupled to the cathode 109.

A first terminal of the startup 222 is coupled to a drain of the ninth transistor 424. A second terminal of the startup 222 is coupled to the cathode 109. A first output terminal of the discharge circuit 210 is coupled to a control terminal of the first switch 420. A second input terminal of the discharge circuit 210 is coupled to the cathode 109. The first transistor 408 and the second transistor 406 of the VF circuitry 402 are diode connected NMOS transistors to set a feed-forward voltage level (e.g., 0.8 V) of the circuitry of the transmitter 102 (e.g., to provide a voltage clamp).

The transistors of the current mirror 214 (408, 410, 412, 414, 416, 418, 422, and 424) mirror the current of the input signal at the anode 108 that is supplied to the oscillator 114 to the other components of the transmitter die 102. The current shunt regulator circuitry 216 enables the shunt transistor 218 to couple the input current of the anode 108 to the cathode 109, responsive getting the required current into the oscillator 114. By shunting the current after the required current, the current range of the transmitter 102 is improved, and overshoot and undershoot during fast transient conditions are avoided.

The bias current supplied by the current mirror 214 to the oscillator 114 drives the PMOS cross-coupled oscillator 114 to energize the transformer 104 responsive to the signal input at the anode 108. The current sense POR 112 drives the fourteenth transistor 440 to couple the input of the oscillator 114 to the cathode 109 (e.g., ground) when the input voltage is below a threshold (e.g., 0.8 V) so that the oscillator 114 is quickly turned off when the input signal drops. The current sense POR 112 facilitates glitch free or reduced glitch oscillator current for different input ramp conditions. The fast clamp circuitry 212 reduces overshoot for fast input transients, prevents leakage in steady state, and avoids false triggers of the discharge circuit due to high overshoot. The startup circuit 222 provides a pulse trigger into the oscillator 114 for fast reliable startup of the oscillator 114 to increase bandwidth. The discharge circuitry 210 detects an input current loss and quickly discharges the internal nodes of the transmitter 102 by closing the first switch 420 and the second switch 430.

FIG. 5 is a circuit diagram of the example oscillator 114 of the transmitter die 102 of FIG. 1 and FIG. 2 coupled to I example winding 105 of the isolation die 104 of FIG. 1. The example oscillator 114 of FIG. 5 is a PMOS cross coupled oscillator. The oscillator 114 of FIG. 2 includes the twelfth transistor 436 and the thirteenth transistor 438. The twelfth transistor 436 includes a source terminal coupled to an input to the oscillator 114, a gate terminal coupled to a drain terminal of the thirteenth transistor 438 and the first terminal or end of the winding 105, and a drain terminal coupled to a gate of the thirteenth transistor 438 and a second end or terminal of the winding 105. A source terminal of the thirteenth transistor 438 is coupled to the input to the oscillator 114. The winding 105 is center-tapped to ground.

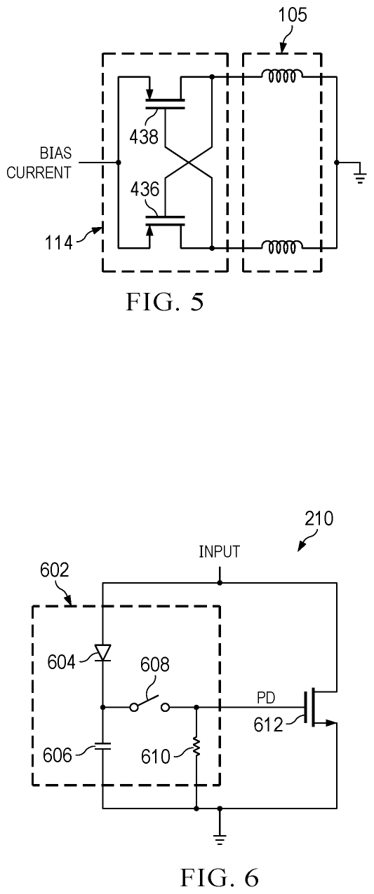

FIG. 6 is a circuit diagram of the example discharge circuit 210 of the transmitter die 102 of FIG. 2. The discharge circuitry 210 is coupled between the input of the transmitter die 102 (e.g., to the anode 108 via the reverse blocking switch 208) and ground (e.g., the cathode 109). The discharge circuit 210 of FIG. 6 includes control circuitry 602 that includes a diode 604, a capacitor 606, a switch 608, and a resistor 610 and a transistor 612 in the arrangement shown. The switch 608 may be implemented as a FET and, in particular, a p-channel metal-oxide semiconductor FET. The diode 604 has an anode and a cathode. Each of the capacitor 606 and the resistor 610 has a first terminal and a second terminal. Each of the switch 608 and the transistor 612 has a first (current) terminal, a second (current) terminal, and a control terminal. In the example of FIG. 6, the transistor 612 is an example of a discharge switch. The diode 604, the capacitor 606, the switch 608, and the resistor 610 are components of control circuitry 602 to generate a signal (PD) to control the transistor 612 responsive to a control signal (e.g., the input at the anode 108 and the cathode 109. The example signal PD can be supplied to the first switch 420 and the second switch 430 of FIG. 4.

The anode of the diode 604 is coupled to an input (e.g., the output of the reverse blocking switch 208). The cathode of the diode 604 is coupled to the first terminal of the capacitor 606. The second terminal of the capacitor 606 is coupled to the cathode 109 of the transmitter 102. The cathode of the diode 604 is also coupled to the first current terminal of the switch 608. The second current terminal of the switch 608 is coupled to the first terminal of resistor 610 and to the control terminal of the transistor 612. The second terminal of the resistor 610 is coupled to the cathode 109 of the transmitter 102.

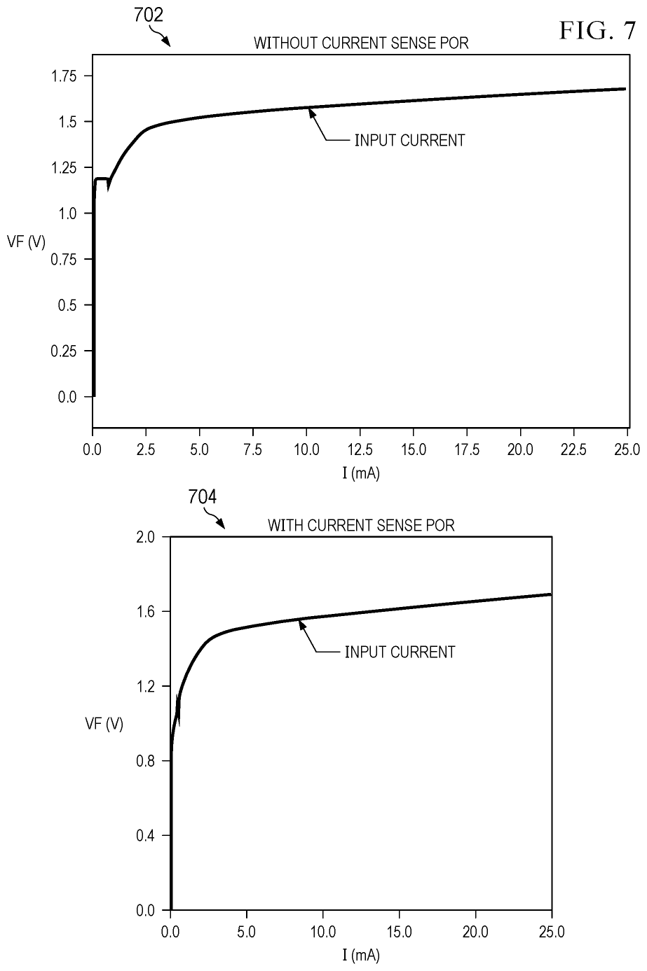

FIG. 7 is a graph 702 of V-I characteristics of a circuit without the oscillator disable circuitry 112 of the transmitter die 102 of FIG. 1 and FIG. 2 and a graph 704 of the V-I characteristics of the circuit with the oscillator disable circuitry 102.

The first graph 702 illustrates the V-I characteristics of an input stage of an opto-emulator that does not include the current sense POR circuitry shown in FIGS. 1, 2, and 4. As shown in the graph 702, the V-I characteristics reflect a discontinuity when oscillator current is cut off by a series switch structure. The second graph 704 illustrates that the discontinuity is not present when the oscillator current is turned off by the parallel NMOS transistor 440 of FIG. 4.

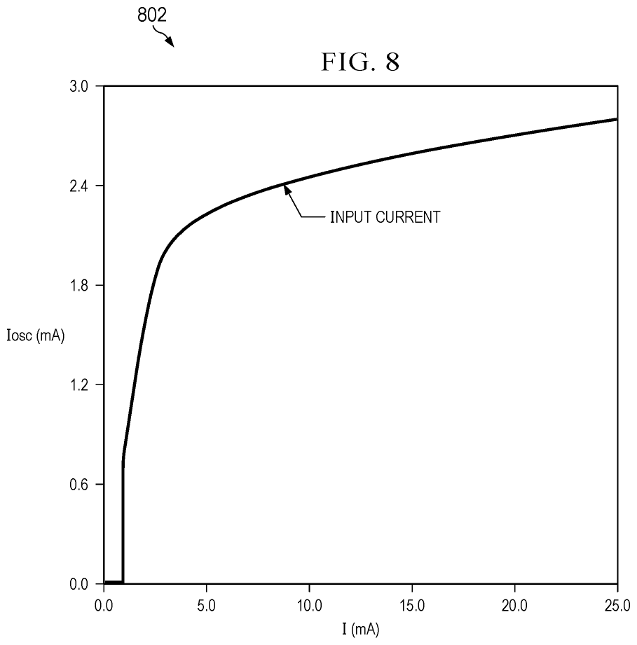

FIG. 8 is a graph of bias current to input current of the example shunt circuitry of the transmitter die 102 of FIG. 1 and FIG. 2. As illustrated, the bias current supplied to the oscillator 114 is mostly constant (e.g., does not include a discontinuity) when the input current varies between 2 mA to 20 mA. The POR circuitry 220 cuts off the oscillator current before the input current reaches 1 mA.

FIG. 9 includes graphs illustrating the improvements provided by the example discharge circuitry 210 and the clamp circuitry 212 of the transmitter die 102 of FIG. 2. As illustrated by graphs 906 and 908 compared with the graphs 902 and 904, the discharge circuitry 210 and the fast clamp circuitry 212 support high speed operation by quickly settling the gate to source voltage of the current mirror 214. In some opto-emulators without the fast discharge circuitry 210, a forward current of 2 mA and data rate of 5 Mbps results in a 14 ns jitter. A forward current of 6 mA and data rate of 25 Mbps results in a 4.12 ns jitter, and a forward current of 20 mA and data rate of 25 Mbps results in a 2.5 ns jitter. In contrast, the transmitter die 102 including the fast discharge circuitry 210 can achieve a forward current of 2 mA and data rate of 5 Mbps resulting in a 7.4 ns jitter, a forward current of 6 mA and data rate of 25 Mbps resulting in a 2.4 ns jitter, and a forward current of 20 mA and data rate of 25 Mbps resulting in a 0.7 ns jitter.

Descriptors “first,” “second,” “third,” etc. are used herein when identifying multiple elements or components which may be referred to separately. Unless otherwise specified or understood based on their context of use, such descriptors do not impute any meaning of priority, physical order, or arrangement in a list, or ordering in time but are merely used as labels for referring to multiple elements or components separately for case of understanding the described examples. In some examples, the descriptor “first” may be used to refer to an element in the detailed description, while the same element may be referred to in a claim with a different descriptor such as “second” or “third.” In such instances, it should be understood that such descriptors are used merely for case of referencing multiple elements or components.

In the description and in the claims, the terms “including” and “having” and variants thereof are intended to be inclusive in a manner similar to the term “comprising” unless otherwise noted. Unless otherwise stated, “about,” “approximately,” or “substantially” preceding a value means +/−10 percent of the stated value. In another example, “about,” “approximately,” or “substantially” preceding a value means +/−5 percent of the stated value. IN another example, “about,” “approximately,” or “substantially” preceding a value means +/−1 percent of the stated value.

The term “couple”, “coupled”, “couples”, and variants thereof, as used herein, may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A. Moreover, the terms “couple”, “coupled”, “couples”, or variants thereof, includes an indirect or direct electrical or mechanical connection.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

Although not all separately labeled in the FIGS., components or elements of systems and circuits illustrated therein have one or more conductors or terminus that allow signals into and/or out of the components or elements. The conductors or terminus (or parts thereof) may be referred to herein as pins, pads, terminals (including input terminals, output terminals, reference terminals, and ground terminals, for instance), inputs, outputs, nodes, and interconnects.

As used herein, a “terminal” of a component, device, system, circuit, integrated circuit, or other electronic or semiconductor component, generally refers to a conductor such as a wire, trace, pin, pad, or other connector or interconnect that enables the component, device, system, etc., to electrically and/or mechanically connect to another component, device, system, etc. A terminal may be used, for instance, to receive or provide analog or digital electrical signals (or simply signals) or to electrically connect to a common or ground reference. Accordingly, an input terminal or input is used to receive a signal from another component, device, system, etc. An output terminal or output is used to provide a signal to another component, device, system, etc. Other terminals may be used to connect to a common, ground, or voltage reference, e.g., a reference terminal or ground terminal. A terminal of an IC or a PCB may also be referred to as a pin (a longitudinal conductor) or a pad (a planar conductor). A node refers to a point of connection or interconnection of two or more terminals. An example number of terminals and nodes may be shown. However, depending on a particular circuit or system topology, there may be more or fewer terminals and nodes. However, in some instances, “terminal”, “node”, “interconnect”, “pad”, and “pin” may be used interchangeably.

Modifications are possible in the described embodiments, and other embodiments are possible, within the scope of the claims.

From the foregoing, it will be appreciated that example apparatus and articles of manufacture have been described that implement improved input stages for opto-emulators. Described apparatus and articles of manufacture improve on existing opto-emulators to provide one or more of increased input current ranges (e.g., 2 mA to 20 mA), improved turn-off of the diode (e.g., 0.8V), improved CMTI (e.g., 85 kV/μs), reduced propagation delay (e.g., 120 ns at 2 mA), and/or increased data rate (e.g., 25 Mbps at 6 mA input current).

What is claimed:

1. A circuit comprising:
a current mirror having first and second outputs;
oscillator circuitry including:
a first transistor having a first terminal coupled to the first output of the current mirror, having a second terminal, and having a control terminal; and
a second transistor having a first terminal coupled to the first output of the current mirror, having a second terminal coupled to the control terminal and the second terminal of the first transistor, and having a control terminal coupled to the second terminals of the first and second transistors; and
current shunt circuitry having a terminal coupled to the second output of the current mirror.

2. The circuit of claim 1, wherein the current shunt circuitry includes:
a third transistor having a first terminal coupled to the second output of the current mirror, a second terminal, and a control terminal coupled to a third output of the current mirror;
a fourth transistor having a first terminal coupled to the third output of the current mirror and the control terminal of the third transistor, a second terminal coupled to ground, and a control terminal coupled to the control terminal of the third transistor;
a resistor coupled between the second terminal of the third transistor and ground; and
a fifth transistor having a first terminal coupled to an input to the circuit, a second terminal coupled to ground, and a third terminal coupled to the first terminal of the third transistor.

3. The circuit of claim 1, further including clamp circuitry coupled to a third output of the current mirror and an input to the circuit, the clamp circuitry having:
a third transistor having a first terminal coupled to the third output of the current mirror, a second terminal coupled to ground, and a control terminal coupled to ground; and
a fourth transistor having a first terminal coupled to the input to the circuit, a second terminal coupled to ground, and a control terminal coupled to the first terminal of the third transistor.

4. The circuit of claim 1, further including oscillator disable circuitry coupled to a third output and a fourth output of the current mirror, the oscillator disable circuitry having:
a third transistor having a first terminal coupled to the third output of the current mirror, a second terminal coupled to ground, and a control terminal coupled to the fourth output of the current mirror;
a fourth transistor having a first terminal coupled to the control terminal of the third transistor, a second terminal, and a control terminal coupled to the control terminal of the third transistor;
a first resistor coupled between the second terminal of the fourth transistor and ground;
a second resistor coupled between the first terminal of the fourth transistor and ground; and
a fifth transistor having a first terminal coupled to the oscillator circuitry, a second terminal coupled to ground, and a control terminal coupled to the third output of the current mirror.

5. The circuit of claim 1, further comprising isolation circuitry coupled to the second terminal of the first transistor and the second terminal of the second transistor, the isolation circuitry having a center tapped to a ground terminal.

6. The circuit of claim 1, further comprising oscillator startup circuitry having a terminal coupled to a third output of the current mirror.

7. The circuit of claim 1, wherein the current mirror includes a third transistor having first terminal coupled to the first terminals of the first and second transistors, a control terminal coupled to the control terminals of the first and second transistors, and a second terminal coupled to the current shunt circuitry, the circuit further including:
a switch coupled between the first terminal of the third transistor and the control terminal of third transistor, and a control terminal; and
a discharge circuit having a first terminal coupled to an input to the circuit, a second terminal coupled to ground, a first output coupled to the control terminal of the switch and a second output coupled to an input of the current shunt circuitry.

8. A circuit comprising:
a current mirror having first and second outputs;
oscillator circuitry including:
a first transistor having a first terminal coupled to the first output of the current mirror, having a second terminal, and having a control terminal; and
a second transistor having a first terminal coupled to the first output of the current mirror, having a second terminal coupled to the control terminal and the second terminal of the first transistor, and having a control terminal coupled to the second terminals of the first and second transistors; and
oscillator disable circuitry having a first terminal coupled to the second terminal of the current mirror.

9. The circuit of claim 8, further including current shunt circuitry having a terminal coupled to a third output and a third terminal of the current mirror.

10. The circuit of claim 8, wherein the oscillator disable circuitry includes:
a third transistor having a first terminal coupled to the second terminal of the current mirror, a second terminal coupled to ground, and a control terminal coupled to a third terminal of the current mirror; and
a fourth transistor having a first terminal coupled to the third terminal of the current mirror, a second terminal, and a control terminal coupled to the control terminal of the third transistor.

11. The circuit of claim 10, wherein the oscillator disable circuitry further includes a fifth transistor having a first terminal coupled to the first terminals of the first and second transistors of the oscillator circuitry, a second terminal coupled to ground, and a control terminal coupled to the second terminal of the current mirror and the first terminal of the third transistor.

12. The circuit of claim 8, further including clamp circuitry coupled to a third terminal of the current mirror and an input to the circuit, the clamp circuitry having:
a third transistor having a first terminal coupled to the third terminal of the current mirror, a second terminal coupled to ground, and a control terminal coupled to ground; and
a fourth transistor having a first terminal coupled to the input to the circuit, a second terminal coupled to ground, and a control terminal coupled to the first terminal of the third transistor.

13. The circuit of claim 8, wherein the oscillator disable circuitry includes:
a third transistor having a first terminal coupled to the third output of the current mirror, a second terminal coupled to ground, and a control terminal coupled to the fourth terminal of the current mirror;
a fourth transistor having a first terminal coupled to the control terminal of the third transistor, a second terminal, and a control terminal coupled to the control terminal of the third transistor;
a first resistor coupled between the second terminal of the fourth transistor and ground;
a second resistor coupled between the first terminal of the fourth transistor and ground; and
a fifth transistor having a first terminal coupled to the oscillator circuitry, a second terminal coupled to ground, and a control terminal coupled to the third output of the current mirror.

14. The circuit of claim 8, further comprising isolation circuitry coupled to the second terminal of the first transistor and the second terminal of the second transistor, the isolation circuitry having a center tapped to a ground terminal.

15. The circuit of claim 8, further comprising oscillator startup circuitry having a terminal coupled to a third terminal of the current mirror.

16. The circuit of claim 8, wherein the current mirror includes a third transistor having first terminal coupled to the first terminals of the first and second transistors, a control terminal coupled to the control terminals of the first and second transistors, and a second terminal, the circuit further including:
a switch coupled between the first terminal of the third transistor and the control terminal of the transistor, and a control terminal; and
a discharge circuit having a first terminal coupled to an input to the circuit, a second terminal coupled to ground, a first output coupled to the control terminal of the switch.

17. A circuit comprising:
a transmitter circuit having:
a current mirror circuit including a first output, a second output, and a third output;
an oscillator circuit having an input coupled to the first output of the current mirror circuit, a first output, and a second output; and
current shunt circuitry having a terminal coupled to the second output of the current mirror circuit; and
oscillator disable circuitry having a first terminal coupled to the third output of the current mirror circuit;
a receiver circuit having first and second inputs; and
an isolation circuit having first and second terminals coupled to the first and second outputs of the oscillator circuit and third and fourth terminals coupled to the first and second inputs of the receiver circuit.

18. The circuit of claim 17, wherein the isolation circuit includes a transformer having:
first windings coupled to the first and second terminals;
second windings coupled to the first and second outputs;
an isolation barrier positioned between the first windings and the second windings; and
a center-tapped ground connection.

19. The circuit of claim 18, wherein the oscillator circuit includes
a first transistor having a first terminal coupled to the first output of the current mirror circuit, having a second terminal coupled to the first windings, and having a control terminal; and
a second transistor having a first terminal coupled to the first output of the current mirror circuit, having a second terminal coupled to the control terminal and the second terminal of the first transistor and the second windings, and having a control terminal coupled to the second terminals of the first and second transistors.

20. The circuit of claim 19, wherein the current shunt circuitry includes:
a third transistor having a first terminal coupled to the second output of the current mirror circuit, a second terminal, and a control terminal coupled to a fourth output of the current mirror circuit;
a fourth transistor having a first terminal coupled to the fourth output of the current mirror circuit and the control terminal of the third transistor, a second terminal coupled to ground, and a control terminal coupled to the control terminal of the third transistor;
a resistor coupled between the second terminal of the third transistor and ground; and
a fifth transistor having a first terminal coupled to an input to the circuit, a second terminal coupled to ground, and a third terminal coupled to the first terminal of the third transistor.
